(19) United States
(12) Patent Application Publication
(10) Pub. No.: US 2023/0001816 A1
(43) Pub. Date: Jan. 5, 2023

(54) SYSTEMS AND RELATED METHODS FOR THE DESIGN OF ELECTRIC VEHICLE INFRACSTRUCTURE

(71) Applicant: KELLOGG BROWN & ROOT LLC, Houston, TX (US)

(72) Inventors: David John Cole, Surrey (GB); Aron Dominic Pain, Middlesex (GB); William Ferrier, Surrey (GB)

(73) Assignee: KELLOGG BROWN & ROOT LLC, Houston, TX (US)

(21) Appl. No.: 17/856,234

(22) Filed: Jul. 1, 2022

Related U.S. Application Data
(60) Provisional application No. 63/218,162, filed on Jul. 2, 2021.

(51) Int. Cl. B60L 53/62; B60L 53/67; B60L 53/64

(52) U.S. Cl. CPC B60L 53/62; B60L 53/67; B60L 53/64

(57) ABSTRACT

A method of designing a charging station to charge electric vehicles at a selected site includes the steps of compiling a set of engineering rules; encoding the set of engineering rules in a processor: obtaining non-site specific information from suppliers and manufactures; storing non-site specific information in a database; obtaining site specific information for the selected site; conveying the site specific information via a user interface to the database; generating deliverables using at least the set of engineering rules, the non-site specific information and the site specific information; and sending the deliverables to an end user. Each engineering rule represents a predetermined design decision.

### CROSS-REFERENCE TO RELATED APPLICATION

This application claims the benefit of Provisional Patent Application No. 63/218,162 filed Jul. 2, 2021, which is incorporated by reference herein in its entirety.

### TECHNICAL FIELD

The present disclosure relates to devices and methods useful for designing and constructing electric vehicle infrastructure.

### BACKGROUND

Among the challenges posed by transitioning away from fossil fuels is the need to provide accessible stations at which electric vehicles can be charged. Over the last several decades, urbanization of population centers has resulted in many suitable locations for stations being subjected to various restrictions. These restrictions may be related to physical space, terrain, available utility resources, access to roads, governmental regulations, etc. These restrictions may impose challenges to applying the same station configuration at each prospective site for a charging station. Because the number of charging stations required will rapidly increase in the next few years, there is a need to evaluate and develop a large number of suitable sites of charging stations despite the unique restrictions each suitable site may have. The present disclosure addresses this need as well as other needs of the prior art.

### SUMMARY

In aspects, the present disclosure provides a method of designing a charging station to charge electric vehicles at a selected site. The method may include the steps of compiling a set of engineering rules, wherein each engineering rule represents a predetermined design decision; encoding the set of engineering rules in a processor; obtaining non-site specific information from suppliers and manufactures; storing non-site specific information in a database; obtaining site specific information for the selected site; conveying the site specific information via a user interface to the database; generating deliverables using at least the set of engineering rules, the non-site specific information and the site specific information; and sending the deliverables to an end user.

It should be understood that certain features of the disclosure have been summarized rather broadly in order that the detailed description thereof that follows may be better understood, and in order that the contributions to the art may be appreciated. There are, of course, additional features of the disclosure that will be described hereinafter and which will in some cases form the subject of the claims appended thereto.

### BRIEF DESCRIPTION OF THE DRAWINGS

For detailed understanding of the present disclosure, references should be made to the following detailed description taken in conjunction with the accompanying drawings, in which like elements have been given like numerals and wherein:

FIG. 1 schematically illustrates a system for designing stations for charging electric vehicles according to one embodiment of the present disclosure; and

FIG. 2 illustrates a flowchart depicting a method for designing stations for charging electric vehicles according to one embodiment of the present disclosure.

### DETAILED DESCRIPTION

In aspects, the present disclosure provides systems and related methods for efficiently evaluating the feasibility of sites for use as an electric vehicle (EV) charging station and generating the engineering designs for a selected site. By engineering, it is meant designs relating, but not limited to, electrical designs, civil designs, costs, safety, etc. The present disclosure is susceptible to embodiments of different forms. There are shown in the drawings, and herein will be described in detail, specific embodiments of the present disclosure with the understanding that the present disclosure is to be considered an exemplification of the principles of the disclosure, and is not intended to limit the disclosure to that illustrated and described herein.

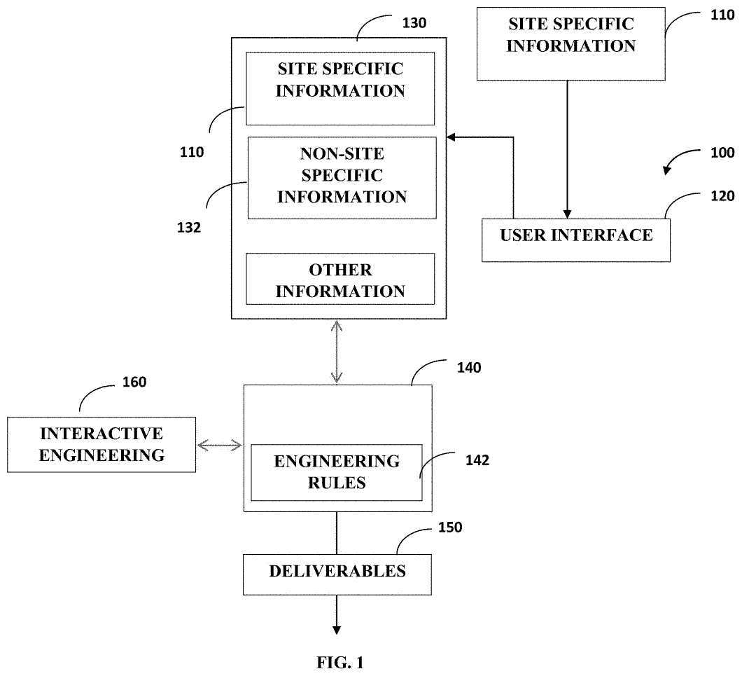

Referring to FIG. 1, there is illustrated a non-limiting embodiment of a system 100 for efficiently evaluating and developing a prospective site for a charging station for electric vehicles. Generally, a user enters site-specific information 110 into a user interface 120. The site-specific information 110 includes details such as the physical attributes of the prospective site. The user interface 120 communicates the entered information to a database 130. The database 130 stores non site-specific information 132, as well as the site-specific information 110 and secondary information 134. The database 130 interacts with a processor 140 encoded with engineering rules 142. The ultimate product of this interaction are deliverables 150 that may be used to construct a charging station at the prospective site. As will be appreciated from the discussion below, utilizing the engineering rules 142 in conjunction with the non site-specific information 132 enables the analyses and designs performed for one site to be re-used, at least to some degree, in the analyses and designs for subsequent sites.

The site-specific information 110 includes information that is relevant to the engineering design of a charging station. As used herein, the term “site-specific” means information that physically defines the prospective site and the physical characteristics of the desired charging station. The site-specific information 110 may include information obtained during a site survey during which personnel measure property features, take visual images, evaluate conditions, etc. The site-specific information 110 may also be obtained using public or private databases. For example, by using GPS coordinates, information regarding terrain, topography, and roadways may be obtained. The user may also enter the desired features of the charging station, e.g., type of location (e.g., above ground, underground, etc), charger types, number of bays, canopy, lighting, CCTV, external connectivity, etc.

The site-specific information 110 is entered into the user interface 120, which may be configured as a website front end. The user interface 120 transmits the entered information to the database 130, which may be a cloud database. The database 130 stores the site-specific information 110, non-site specific information 132, and well as secondary information 134. The non-site specific information 132 may include information that relates to the parts, equipment, devices, and materials used to construct a charging, station. For example, the non-site specific information 132 may include specifications, dimensions of components, availability of components, and costs for chargers, cabling, substations, etc. As used herein, non-site specific information is information that may be relevant to the design and/or construction of two or more sites. By way of example, GPS coordinates will be unique to each site; i.e., site specific. The dimensions and costs of a charger will likely be the same or similar across two or more sites; i.e., non-site specific.

Secondary information 134 may include information that relates to specific requirements received from the client in their design criteria, including but not limited to aspects such as the marketing and branding appearance of the EV Charging Site etc. Secondary information 134 may also include standards which are specific to the country or region in which the site is located.

To initiate the generation of the deliverables 150, the database 130 conveys the relevant stored site and non-site information to the processor 140. The processor 140 includes engineering rules 142 that implement predetermined design decisions to be applied to a selected site. Illustrative, but not exhaustive, examples of design decisions include: identifying the number of bays for EV charging for a given plot area, identifying locations for individual EV chargers, assigning EV chargers to bays, locating “L&SP” distribution boards, fire detection panels and communication panels, identifying available cable routes, etc.

The design decision may be constructed as a rule. For example, a rule to assign EV chargers to a bay may be expressed as follows: (i) if single vehicle charger locate charger at end of bay, (ii) if dual vehicle charger locate charger at end of bay at midpoint, and (iii) each arrangement needs ‘bumper’ bar/post stops located either to be hit by EV bumper or for the wheel to hit when parking. In another example, the rules for the number of sub-distribution boards may be expressed as follows: (i) default is that all chargers are fed from sub-distribution boards for ease of access, (ii) if number of sub-distribution boards is zero, then all chargers are fed from the main substation switchgear, (iii) if fed from sub-distribution boards, then each charger is fed from a maximum of a 250 A MCCB (this allows for up to 120 kW charger), (iv) rating of sub-distribution board feeder=Round down (250 A×0.95/FLC), (v) each sub distribution board can feed a maximum of 630 A (allows for 3×120 kW or 6×60 kW chargers), and (vi) number of chargers per board =Round Round down (630 A×0.95/FLC). In one embodiment, the engineering rules 142 may be encoded in commercially available software solutions such as AVEVA E3D, Hexagon Integraph, AutoDesk, and MicroStation.

Human input, or interactive engineering 160, may be used for certain design aspects. For example, the engineering rules may identify locations for sub-distribution boards based on rules that minimize cable routing, which are then adjusted as needed by a human for considerations such as access. Furthermore, interactive engineering 160 is a powerful tool to deliver optimization of EV charging infrastructure sites, where the system identifies the opportunity to revise layouts to achieve an optimized design both commercially and technically.

Using the site and non-site specific information 110, 132, along with the engineering rules 142 and interactive engineering, the processor 140 generates the deliverables 150 required for the completion of the detailed design process for each electric vehicle charging site. The deliverables 150 may include, but not be limited to, Material Take Off (MTO), cable and fault calculations, construction drawings, overall layout drawing, cost estimate, 2D Drawing, and 3D Navisworks model, or other equivalent commercially available software. Other deliverables include, but are not limited to, single line diagram, electrical load list, cable schedule, cable routing, charger foundation drawings, canopy foundation drawings, and canopy general arrangement drawings etc.

The deliverables 140 may also include the assessment and calculation of the carbon footprint impact of an EV charging design for each site. Interactive engineering 160 with these results allows selection of EV designs that have the lowest overall carbon footprint.

Blockchain technology will be used throughout the system 100 to provide an immutable leger of the EV charging asset. All information entered via the user interface 120, interactive engineering activities 160, and database entries are tracked on the blockchain network. Using smart contracts stored on the blockchain and executed automatically, when contractually defined conditions are achieved, including the production of deliverables 150, digital signatures are requested authorizing payment.

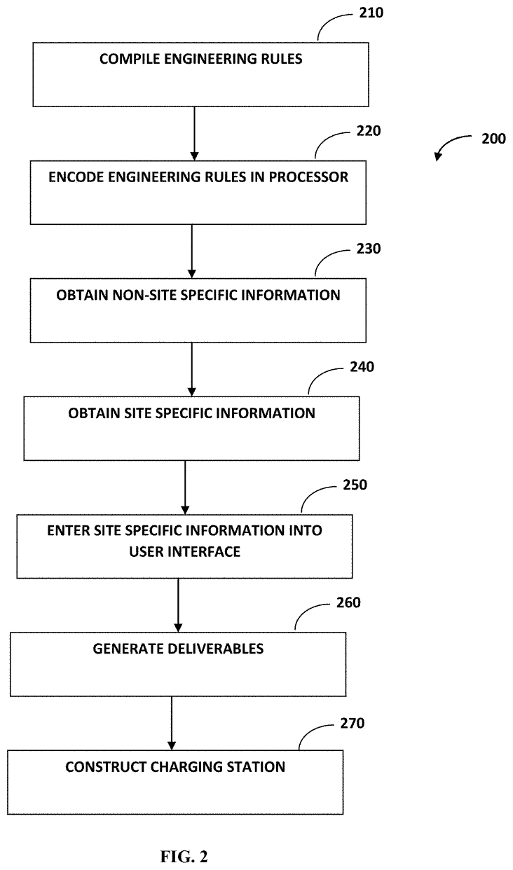

Referring to FIG. 2, there is shown a non-limiting embodiment of a method 200 according to the present disclosure for efficiently evaluating, optimizing and developing a prospective site for a charging station for electric vehicles.

At step 210, a set of engineering rules is compiled. Each engineering rule represents a predetermined design decision that has generic application across two or more sites. As noted previously, these rules may embodiment regulatory requirements, conventional engineering practices, etc. At step 220, the engineering rules are encoded in a processor. The processor may be a general purpose computer that runs commercially available engineering software. At step 230, non-site specific information is loaded into and stored in a database. This information, which may include costs and specifications, may be received from equipment suppliers, construction companies, and other entities that may participate in the construction of the charging station at the selected site. At step 240, a user obtains site specific information for the selected site. This information may be obtained during a physical inspection of the selected site and also from public and/or private databases. At step 250, the site specific information is entered via a user interface into the database. At step 260, the set of engineering rules, the non-site specific information, the site specific information and other information are used to generate deliverables. Deliverables may be generated to a level of detail which supports a EV charging site feasibility determination at step 265. A feasibility determination may include a feasibility design package that furnishes information relating to cost, and possibly other aspects that assist an entity to determine whether or not to proceed with constructing the EV charging station. For example, the feasibility design package may include information relating to costs, schedules, capacities, and/or other factors that enable the entity to determine whether or not an investment of time, financial resources, and/or effort will generate a favorable return. If so, the deliverables may be used, at step 270, to construct the EV charging station. In some situations, the method may omit step 265.

At step 270, these deliverables are used to construct the charging station. It should be understood that the steps 230/240 and 250 may be reordered as needed to suit a particular situation. Moreover, the information in the database 130 and/or the processor 140 may be periodically or continuously updated.

It should be appreciated that the teachings of the present disclosure may be used to construct EV charging stations. That is, construction activities may be supported by receipt of the deliverables, which can then be used to erect structures, run electrical lines, install equipment, etc.

The foregoing description is directed to particular embodiments of the present disclosure for the purpose of illustration and explanation. It will be apparent, however, to one skilled in the art that many modifications and changes to the embodiment set forth above are possible without departing from the scope of the disclosure. It is intended that the following claims be interpreted to embrace all such modifications and changes.

What is claimed is:

1. A method of designing a charging station to charge electric vehicles at a selected site, comprising:
compiling a set of engineering rules, wherein each engineering rule represents a predetermined design decision;
encoding the set of engineering rules in a processor;
obtaining non-site specific information from suppliers and manufacturers;
storing non-site specific information in a database;
obtaining site specific information for the selected site;
conveying the site specific information via a user interface to the database;
generating deliverables using at least the set of engineering rules, the non-site specific information, and the site specific information; and
sending the deliverables to an end user.

2. The method of claim 1, further comprising developing a design feasibility package using the deliverables.

3. The method of claim 1, further comprising constructing the charging station using the deliverables.

4. The method of claim 1, further comprising obtaining and storing secondary information in a database, wherein the secondary information is also used to generate the deliverables.

5. The method of claim 4, wherein the secondary information includes at least one of:
marketing requirements, branding appearance, jurisdiction standards, and regulatory standards.

6. The method of claim 1, further comprising using Blockchain technology during the compiling, encoding, obtaining, storing, conveying, generating, and using steps.

7. The method of claim 6, wherein the Blockchain technology is used to at least one of:
(i) deliver an immutable record of transactions, and (ii) automatically execute contract conditions.

8. A system for evaluating and developing a prospective site for a charging station for electric vehicles, comprising:
a user interface configured to receive site-specific information;
a database configured to store at least non site-specific information and site-specific information received from the user interface; and
a processor configured to access the database and encoded with engineering rules, the processor configured to generate at least one deliverable for constructing the charging station at the prospective site using the engineering rules, the site-specific information, and the non site-specific information.

9. The system of claim 8, wherein the site-specific information physically defines the prospective site and the physical characteristics of the charging station.

10. The system of claim 8, wherein the non-site specific information defines at least one common feature of at least two charging station sites.

11. The system of claim 8, wherein the at least one deliverable includes: Material Take Off (MTO), a cable and fault calculation, a construction drawing, an overall layout drawing, a cost estimate, a 2D drawing, and a 3D model.

12. The system of claim 8, wherein the engineering rules include at least one of:
identifying the number of bays for a given plot area, identifying locations for individual chargers, assigning chargers to bays, and identifying available cable routes.

13. The system of claim 8, wherein the processor is configured to use Blockchain technology.

14. The system of claim 13, wherein processor is further configured to use the Blockchain technology to at least one of: (i) deliver an immutable record of transactions, and (ii) automatically execute contract conditions.

15. The system of claim 8, wherein the database is configured to store secondary information in the database, wherein the processor is further configured to use the secondary information to generate the deliverables.
